(19) United States
(12) Patent Application Publication
(10) Pub. No.: US 2006/0131654 A1
(43) Pub. Date: Jun. 22, 2006

(54) Diode with reduced forward-bias resistance and shunt capacitance

(76) Inventor: John W. Poulton, Chapel Hill, NC (US)

Correspondence Address: SHEMWELL MAHAMEDI LLP, 4880 STEVENS CREEK BOULEVARD, SUITE 201, SAN JOSE, CA, 95129, US

(21) Appl. No.: 11/016,234

(22) Filed: Dec. 17, 2004

(51) Int. Cl. H01L 23/62

(52) U.S. Cl. 257/355

(57) ABSTRACT

A diode having reduced forward-bias resistance and shunt capacitance. The diode includes a lightly doped region of a semiconductor substrate, a carrier injection region and an ohmic contact region. The carrier injection region is disposed within the lightly doped region and has a plurality of sides of substantially uniform length. The ohmic contact region is disposed about a perimeter of the carrier injection region.

### FIELD OF THE INVENTION

The present invention relates to the field of electro-static discharge protection.

### BACKGROUND

Electrostatic discharge (ESD) protection schemes in modern integrated circuits commonly include breakdown-configured field effect transistors (FETS) that avalanche when a first-breakdown voltage is reached, shunting destructive currents away from internal circuitry and clamping signal lines at levels below gate overstress voltages. FIG. 1 illustrates a typical prior-art ESD protection scheme having such breakdown-configured FETs 101a, 101b coupled between a signal line 102 and respective power-supply lines 104a, 104b to shunt current from an ESD event at signal input s1 away from an internal gate 105. Unfortunately, while gate overstress voltages have continued to shrink with process geometry, FET first-breakdown voltages have not. In particular, as complementary metal-oxide semiconductor (CMOS) geometries drop below 100 nanometers (nm), gate overstress voltages have dropped to levels at or below the FET first-breakdown voltage, rendering breakdown-configured FETs increasingly inadequate to protect against ESD events. Also, the input capacitance presented by breakdown-configured FETs is becoming an intolerable source of signal loss as signaling rates progress higher into the Gigahertz range.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a prior-art electrostatic discharge (ESD) protection scheme using breakdown-configured field-effect transistors;

FIG. 2 illustrates an embodiment of an ESD protection circuit in which diodes are cross-coupled between power supply conductors and signal conductors to provide ESD clamps;

FIG. 3 illustrates an exemplary I-V curve of a diode that may be used within the ESD protection circuit of FIG. 2;

FIG. 4 is a waveform diagram illustrating the voltage clamping operation of the ESD protection circuit of FIG. 2;

FIG. 5 illustrates the operation of the ESD protection circuit of FIG. 2 when positive and negative spikes of an ESD event are received at a signal line input and supply line input;

FIG. 6 illustrates the operation of the ESD protection circuit of FIG. 2 when positive and negative spikes of an ESD event are received at a supply line input and ground line input;

FIG. 7 illustrates a diode-based ESD protection circuit according to an alternative embodiment;

FIG. 8 illustrates a diode-based ESD protection circuit according to another alternative embodiment;

FIGS. 9A and 9B are top and cross-sectional views of an exemplary junction diode that may be used to implement the diodes within the ESD protection circuits described in reference to FIGS. 2-8; and

FIGS. 10A and 10B illustrate an alternative embodiment of a junction diode having an increased P-N junction area-to-perimeter ratio relative to the junction diode of FIGS. 9A and 9B.

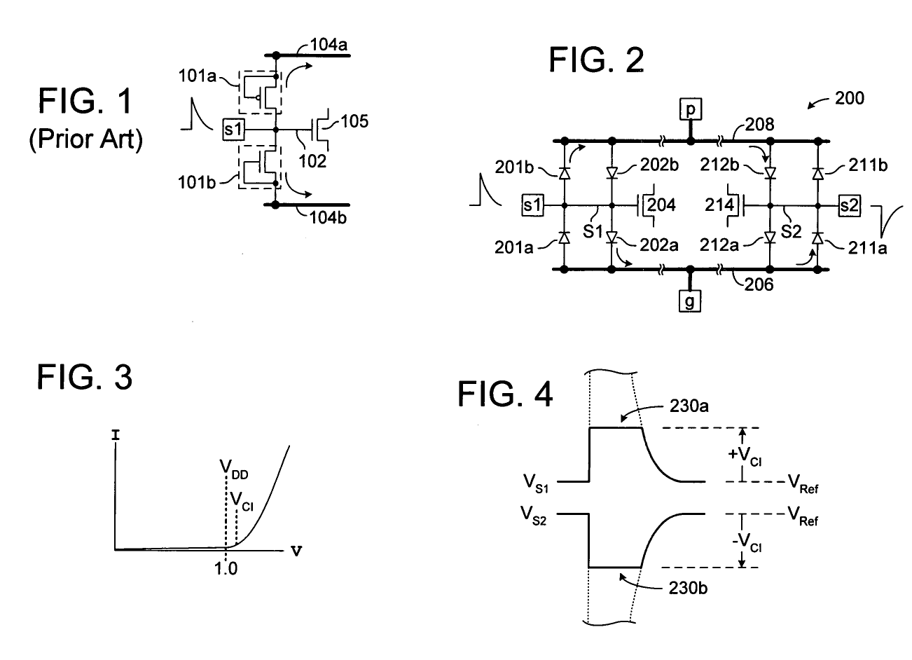

### DETAILED DESCRIPTION

In the following description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. Also signals referred to herein as clock signals may alternatively be strobe signals or other signals that provide event timing. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘\overline{<signal name>}’) is also used to indicate an active low signal. The term “exemplary” is used herein to express an example, and not a preference or requirement.

Diode-based ESD protection circuits are disclosed herein in various embodiments motivated, at least in part, by the observation that power-supply voltages in modern semiconductor processes are dropping below diode cut-in voltages (i.e., the voltage at which appreciable forward-biased conduction begins) and the insight that diodes may therefore be coupled in a forward-biased configuration between power-supply lines and signal lines to provide ESD shunt paths. In deep submicron CMOS processes, for example (i.e., critical dimension ≦90 nm), the power-supply voltage is generally at or below one volt, and the gate overstress voltage is in the neighborhood of 1.5-2.0 volts. Because the cut-in voltage of P-N junction diodes in such processes is just over a volt, such diodes may be cross-coupled between power-supply lines and signal lines to form effective ESD shunts, clamping signal lines below gate overstress voltage levels. Also, the product of shunt capacitance (Ci) and forward-bias resistance (Rf) for modern P-N junction diodes tends to be much lower than breakdown-configured FETs so that, when applied in high-speed signaling environments, the diode-based ESD protection circuits disclosed herein tend to exhibit improved clamping characteristics and substantially reduced signal loss relative to FET-based circuits.

### Diode-Based ESD Protection

FIG. 2 illustrates an embodiment of an ESD protection circuit 200 in which diodes are cross-coupled between power supply conductors and signal conductors to provide ESD clamps. The ESD protection circuit 200 is included within an integrated circuit (the “host IC”) that is powered by a supply voltage of approximately one volt or less (e.g., as in the case of an IC fabricated using a deep submicron CMOS process). Consequently, P-N junction diodes (“junction diodes”) exhibiting a cut-in voltage, V_{CI}, just above the one volt supply voltage, V_{DD}, as illustrated in FIG. 3, may be coupled in a forward-biased configuration between the supply conductors and the signal conductors and yet exhibit negligible current flow during powered operation of the host IC (i.e., the diodes operate in the cutoff region at normal supply voltage levels). Accordingly, diodes 201a, 202a may be cross-coupled between signal line S1 and ground line 206 for ESD clamping purposes, with diode 201a being coupled in a reverse-biased configuration (i.e., anode coupled to the more negative node, 206, and cathode coupled to the more positive node, S1) and diode 202a being coupled in a forward-biased configuration (i.e., anode coupled to the more positive node, S1, and cathode coupled to the more negative node, 206). Diodes 201b and 202b are likewise cross-coupled between signal line S1 and supply line 208, with diode 201b coupled in a reverse-biased configuration and diode 202b coupled in a forward-biased configuration. Diodes 211a, 212a correspond to diodes 201a, 202a and are cross-coupled between signal line S2 and ground line 206, while diodes 211b, 212b correspond to diodes 201b, 202b and are cross-coupled between signal line S2 and supply line 208. By this arrangement, each of the cross-coupled diode pairs includes one diode coupled in a reverse-biased orientation relative to the anticipated operating voltages on the signal and power supply lines, and one diode coupled in the forward-biased orientation. Note that the term “ground” is used herein merely to mean a power-supply return voltage and should not be construed as limiting the potential on line 206 to earth-ground.

Still referring to FIG. 2, the signal lines, S1 and S2, and supply and ground lines, 206 and 208, are coupled to external contacts of the host IC via respective pads (s1, s2, p and g) or other contact points and therefore are susceptible to ESD events when the host IC is powered down (e.g., during fabrication and production-time handling). Such ESD events typically manifest as large positive and negative voltage spikes (i.e., representing the positive and negative terminals of an electrostatic charge source) which, in absence of the ESD protection circuit 200, may deliver a destructive amount of energy to internal circuitry of the host IC. For example, the 1-4 kilovolt electrostatic discharge typical of a charged human body would likely break down the under-gate dielectric of gate-coupled transistors 204 and 214 (which may form, for example, input nodes of a receiver circuit). Destruction due to second-breakdown phenomena is likely in the case of drain-coupled internal circuits such as output drivers and the like.

In FIG. 2, the positive and negative voltage spikes of an ESD event are assumed to be received at pads s1 and s2, respectively, while the host IC is powered down. Consequently, as shown in FIG. 4, the voltage on signal line S1 (V_{S1}) spikes upward relative to the voltage level, V_{REF}, on the supply and ground lines (208, 206), while the voltage on signal line S2 (V_{S2}) spikes reciprocally downward. When V_{S1} reaches the diode cut-in voltage, V_{CI}, forward-biased conduction begins in diode 201b, clamping the voltage between signal line S1 and the supply line 208 at a level substantially near V_{CI} (i.e., a diode drop) as shown at 230a. Diode 202a also begins forward-bias conducting when V_{S1} reaches V_{CI} to clamp the voltage between signal line S1 and the ground line 206 at or near V_{CI}. Similarly, when V_{S2} reaches −V_{CI}, forward-biased conduction begins in diodes 211a and 212b enabling the current flowing into the ESD protection circuit at pad s1 to exit at pad s2, and clamping the voltage between signal line S2 at a diode drop (i.e., V_{CI}) below the ground and supply line voltage levels as shown at 230b. Thus, the voltage appearing at the internal circuitry coupled to signal lines S1 and S2 (i.e., represented by transistors 204 and 214 in FIG. 2) does not exceed (or fall below) the ground and supply line voltages by substantially more than a diode drop; a voltage less than the gate overstress voltage for modern CMOS processes.

In the case of an ESD event having the opposite polarity of that shown in FIG. 2, diodes 212a, 211b 201a and 202b, will operate in generally the same manner as counterpart diodes 202a, 201b, 211a and 212b to clamp the voltages on signal lines s1 and s2 below the gate overstress voltage. That is, diodes 212a and 211b will forward-bias conduct to clamp signal line s2 at a diode drop above the ground and supply line voltages, and diodes 201a and 202b will forward-bias conduct to clamp signal line s1 at a diode drop below the ground and supply line voltages.

Still referring to FIG. 2, it should be noted that while two pairs of cross-coupled diodes are coupled to each signal line (four diodes in all) in the ESD protection circuit 200, the current carried by the two pairs of diodes is split between each diode pair in discharging an ESD-generated potential between pads s1 and s2. That is, half the discharge current flows through a diode in diode pair 201a/202a and half flows through a diode in diode pair 202a/202b. Consequently, each individual diode may be formed in half the die area that would otherwise be required if each diode were to bear the entire discharge current (the current-carrying capacity of a diode is generally proportional to its cross-sectional area), so that relatively small, low-capacitance structures may be used to form the diodes 201a/b, 202a/b, 211a/b and 212a/b.

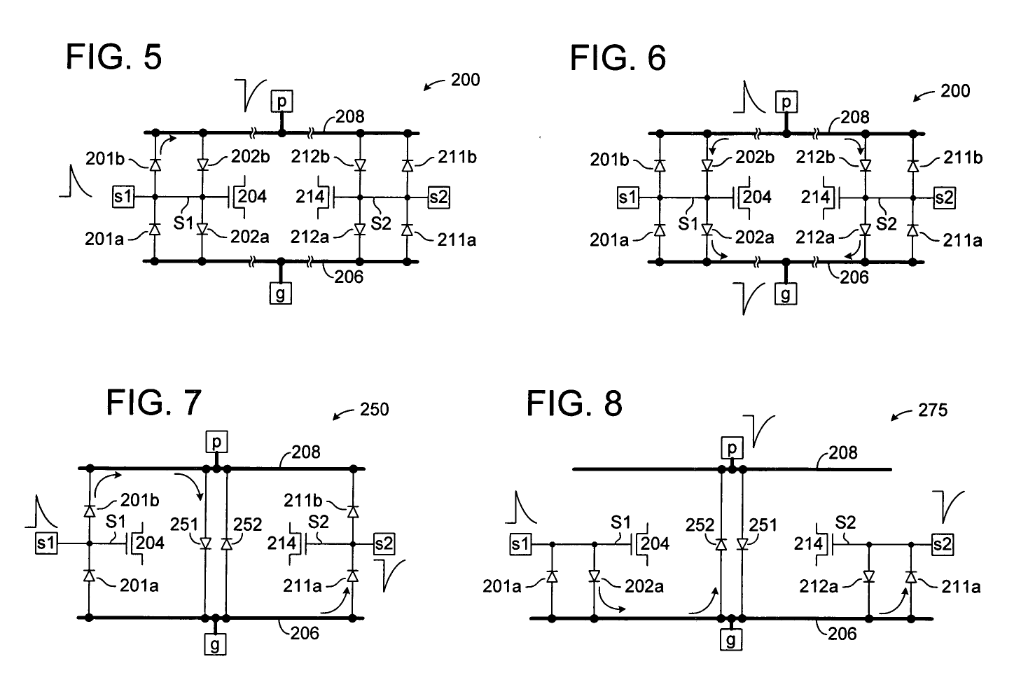

FIG. 5 illustrates the operation of the ESD protection circuit 200 of FIG. 2 when positive and negative spikes of an ESD event are received at a signal line pad (s1) and the supply line pad (p), respectively. In this circumstance, V_{S1} spikes upward relative to V_{REF} and the supply line voltage simultaneously spikes downward relative to V_{REF} until the potential between signal line S1 and supply line 208 exceeds the cut-in voltage of diode 201b. At this point, diode 201b begins conducting current, clamping V_{S1} at one diode drop above the supply line voltage, thereby preventing the S1-voltage line potential from exceeding the gate overstress voltage of transistor 204. In many integrated circuit applications, the coupling between power supply lines is such that the downward spike on supply line 208 will, at least in part, appear on ground line 206, in which case diode 202a may also begin conducting and thus carry a portion of the ESD current (and ensuring that the potential between signal line S1 and ground line 206 does not exceed a diode drop). In applications where ESD spikes do not couple between the power supply lines, a single diode may be required to carry the entire ESD current, meaning that larger diodes may be required in the ESD protection circuit 200. In such applications, the diode-drop potential between signal line S1 and supply line 208 will generally be centered near or around the reference voltage on ground line 206, thereby ensuring that the potential between signal line S1 and ground line 206 will not exceed the gate overstress voltage of transistor 204.

If an ESD event occurs in a polarity opposite that shown in FIG. 5 (i.e., positive spike at the supply line pad (p) and a negative spike at pad s1), the operation will be generally as described above, except with current flowing through diode 202b and, if the ESD spike is coupled between the supply and ground lines, through diode 201a. Also, if the positive or negative counterpart to a spike at pad s1 occurs at the ground line pad (g) instead of the supply line pad (p), current will flow through diodes 201a or 202a, respectively, to dissipate the energy of the ESD event.

FIG. 6 illustrates the operation of the ESD protection circuit 200 of FIG. 2 when positive and negative spikes of an ESD event are received at the supply line pad (p) and ground line pad (g), respectively. In this circumstance, the supply line voltage spikes upward relative to the ground line voltage, causing diode pairs 202b/202a and 212b/212a to conduct current from the supply line to the ground line. By this operation, signal lines S1 and S2 each develop a voltage that is clamped at one diode drop below the supply line voltage and one diode drop above the ground line voltage, thus ensuring that the gate overstress voltage of internal circuitry is not exceeded. If the polarity of the ESD event is reversed, diode pairs 201a/201b and 211a/211b will conduct current from the ground line to the supply line achieving substantially the same protective effect, with signal lines S1 and S2 being clamped one diode drop below the ground line voltage and one diode drop above the supply line voltage. Note that, for this type of ESD event, all of the diode pairs in all I/O circuits on the chip contribute to the ESD current conduction path, providing a very low impedance path for ESD currents.

### Alternative Diode-Based ESD Protection Circuits

FIG. 7 illustrates a diode-based ESD protection circuit 250 according to an alternative embodiment. Instead of providing cross-coupled diodes between signal lines and power-supply lines as in the embodiment of FIG. 2, solitary diodes (201a, 201b, 211a, 211b) are coupled in a reverse-biased configuration between signal lines S1, S2 and power-supply lines 206, 208 with a shunt path established between the supply line 208 and ground line 206 by a pair of cross-coupled shunt diodes 251, 252. By this arrangement, an ESD spike appearing across pads s1 and s2 is discharged via diodes 201b, 251 and 211a, as shown. While this discharge path nominally establishes the potential of signal line S1 at two diode drops above the ground line potential (and signal line S2 at two diode drops below the supply line potential), shunt diodes 251, 252 may be significantly larger than the signal-line-coupled diodes (especially diode 252 as it is normally reverse-biased when power is applied) and therefore may prevent the potential between the power supply lines 206, 208 from substantially exceeding one diode drop, even for large current spikes. Also, the impedance between the power-supply lines 206, 208 is usually small due to on-chip bypass capacitance and inherent capacitance that results from the large number of n-well/substrate junctions, device wiring and so forth. The low impedance tends to clamp the voltage between power-supply lines 206, 208 substantially below a diode drop in many applications, so that the gate potential of devices 204, 214 will not rise significantly more than a single diode drop above the supply and ground line potential. ESD events appearing across the power-supply lines 206, 208 are discharged directly by the shunt diodes 251, 252, and ESD events appearing across a signal line and a power-supply line are discharged by the reverse-biased diode coupled between the two lines. In the case of a high-going spike at the supply line 208 and counterpart low-going spike at a signal line, the ESD current flows first to the ground line 206 via shunt diode 251, then to the signal line (S1 or S2) via the diode coupled between the ground line and signal line.

FIG. 8 illustrates a diode-based ESD protection circuit 275 according to another alternative embodiment. Cross-coupled diode pairs (201a/202b and 212a/212b) are coupled between each signal line and one of the power-supply lines (ground line 206 in this example), with a shunt path established between the supply line 208 and ground line 206 by a pair of cross-coupled diodes 251, 252. By this arrangement, an ESD event appearing across signal pads s1 and s2 is discharged via diodes 202a and 211a which form, in effect, half the discharge path discussed in reference to FIG. 2 (note that the cross-coupled diodes may be drawn as large as necessary to handle the anticipated ESD current). An ESD event of opposite polarity is discharged via diodes 212a and 201a. An ESD event between signal line S1 and the supply line 208 is discharged through diode 202a and shunt diode 252, while the opposite-polarity ESD event is discharged via shunt diode 251 and diode 201a. The discharge path from signal line to supply line 208 includes two diode drops but, as discussed in reference to FIG. 7, the voltage between the ground line 206 and supply line 208 may be clamped at substantially less than a diode drop in many applications, providing an overall ESD clamp at substantially less than two diode drops.

It should be noted that the embodiment of FIG. 8 is particularly well suited to signaling schemes in which a small-swing signal is centered on a voltage nearer to the ground line potential 206 than the supply potential, as such signals will generally not approach the cut-in voltage of the forward-biased diodes 201a, 212a. In alternative embodiments (e.g., in the case of small-swing signals centered on a voltage near the potential of supply line 208), the cross-coupled diodes 201a/202a and 211a/212a may be coupled to supply line 208 instead of ground line 206.

### Junction Diode Construction

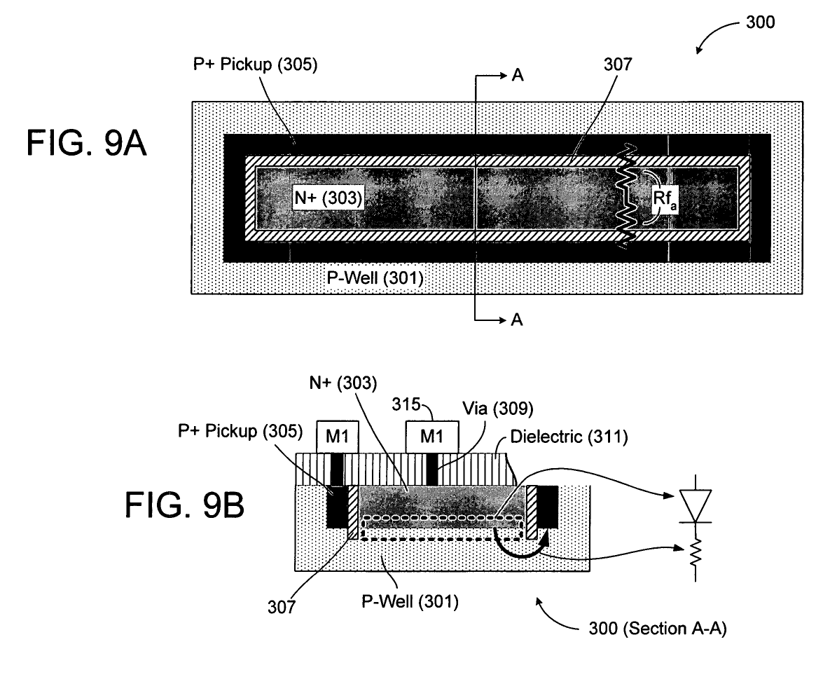

FIGS. 9A and 9B are top and cross-sectional views of an exemplary junction diode 300 that may be used to implement the diodes within the ESD protection circuits described in reference to FIGS. 2-8. The diode 300 is an N⁺/P diode constructed by forming a positively-doped well 301 (p-well) in a silicon substrate (not shown), then forming a relatively heavily doped N+ region 303 (i.e., a carrier-injection region doped with material to increase the concentration of charge carriers) within the p-well 301. As shown in the cross-sectional view of FIG. 9B, the junction between the heavily doped N+ region 303 and more lightly doped p-well 301 constitutes the P-N junction of the diode 300 and provides the diode characteristic. To reduce the forward-bias resistance of the diode and provide a convenient cathode contact point, an ohmic contact region 305 (P+ pickup) formed by a relatively heavily doped P+ region (i.e., doped with material to increase the concentration of positive charge carriers) is disposed about the outer perimeter of the N+ region 303. Also, a trench 307 may be formed around the perimeter of the N+ region 303 and filled with a dielectric (e.g., SiO₂, as in the case of a shallow-trench isolation (STI) process) to isolate the N+ region 303 from the ohmic contact region 305, thereby avoiding undesired leakage from the N+ region 303 to the ohmic contact region 305.

As the ohmic contact region 305 and the N+ region 303 constitute the P and N terminals, respectively, of the P-N junction diode 300, vias 309 or other layer-traversing conductive structures may be provided to establish contact between the diode 300 and a first conductive layer (e.g., a first metal layer, M1, or other layer of conductive material) within an integrated circuit device. As shown in FIG. 9B, the vias 309 may extend, for example, through a layer of silicon dioxide or other dielectric 311 disposed over a surface of the silicon substrate. Additional vias 309 or other conductive structures may be used to connect the nodes of the first conductive layer 315 to yet other conductive layers within the integrated circuit. Also, though not specifically shown, salicides or other contact-facilitating material may be disposed between the vias 309 and N+ region 303 and/or ohmic contact region 305 to facilitate electrical contact. Further, while an N⁺/P diode is shown in FIGS. 9A and 9B, the disposition of the N+ and P+ regions may be reversed and disposed in a lightly doped n-well (or n-type substrate) to form a P⁺/N diode. In practice, both N⁺/P and P⁺/N diodes may be used to provide a desired ESD discharge path. For example, in the embodiment of FIG. 2, diodes 201a and 201b may be implemented by N⁺/P diodes, while diodes 202a and 202b are implemented P⁺/N diodes, thereby coupling the nominally more negative lines to N+ carrier injection regions and the nominally more positive lines to P+ carrier injection regions. Alternative arrangements of N⁺/P and P⁺/N diodes may be used in other ESD protection circuits, including arrangements that include only N⁺/P or only P⁺/N diodes.

### Junction Diode with Reduced Forward-Biased Resistance and Shunt Capacitance

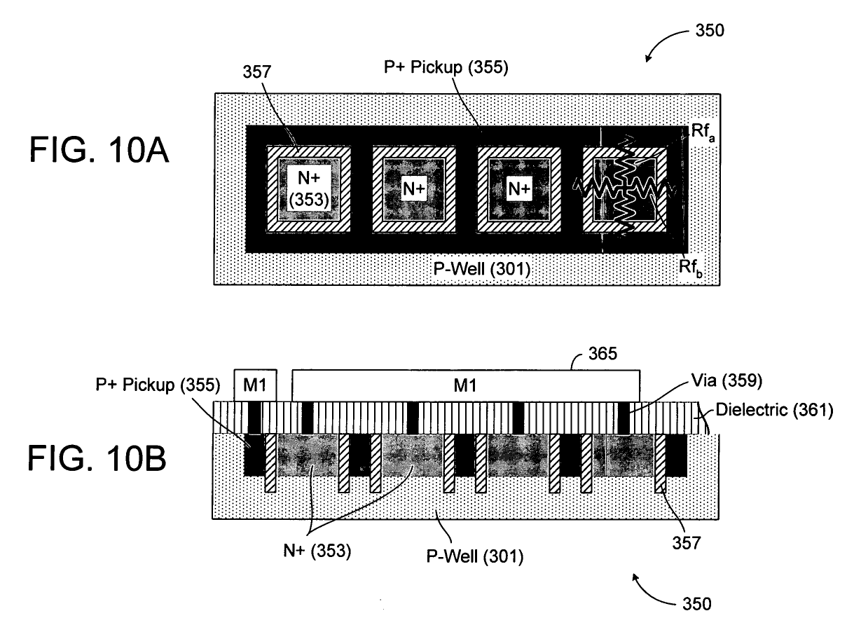

The voltage clamping operation of the ESD protection circuits of FIGS. 2, 7 and 8 generally improves as the forward-bias resistance (Rf) of the constituent diodes is reduced, while frequency response is improved by reduced shunt capacitance (Ci). FIGS. 10A and 10B illustrate an alternative embodiment of a junction diode 350 that is intended to reduce both forward-bias resistance and shunt capacitance by increasing the area-to-perimeter ratio of the P-N junction. Instead of laying out the diode in a long rectangular strip as in diode 300 of FIGS. 9A and 9B, the rectangular N+ region of diode 300 is decomposed into multiple smaller square or substantially square active-area islands 353 (N+ islands) within p-well 301, with each active-area island 353 being surrounded or substantially surrounded by a P+ pickup ring 355 (i.e., ohmic contact region). This layout approach may provide nearly a factor of two reduction in forward-bias resistance per unit area relative to a rectangular-strip layout as current flows in all four directions from each square of P-N junction area, while in the rectangular-strip layout, current flows primarily in two directions per square of P-N junction area. Thus, the forward bias resistance is nearly halved due to the effectively parallel resistive paths Rfₐ and Rf_{b} shown in FIG. 10A as compared to primarily singular resistive path Rfₐ shown in FIG. 9A. The Ci of the multiple substantially square diodes remains the same, or only slightly higher than the Ci of the rectangular-strip diode of the same overall area, so that the product Ci*Rf is approximately halved. Thus, the level of ESD protection is substantially improved without affecting the high-frequency behavior of the I/O circuitry. Alternatively, the overall area of the multiple square diodes may be halved, reducing Ci by approximately a factor of two, while leaving Rf substantially unchanged relative to the rectangular-strip diode. In this case, the level of ESD protection is essentially the same as in the rectangular-strip diode, but the high frequency behavior of the I/O circuitry is substantially improved.

In the embodiment of FIG. 10, each of the N+ islands 353 is surrounded by an isolating material 357 (e.g., a trench filled with SiO₂ or other dielectric) to electrically isolate the heavily doped N+ and P+ regions. Also, as shown in the cross-sectional view of FIG. 10B, multiple vias 359 may extend through dielectric 361 to couple each of the N+ islands 353 to a common node in a first conductive layer 365 (e.g., a metal node within a first metal layer, M1). By this arrangement, the multiple N+ regions collectively form the N terminal of the P-N junction. While a single via is depicted as coupling the ohmic contact region 355 to a conductive structure in the first conductive layer 365, multiple vias may alternatively be coupled to the ohmic contact region 355 to avoid extended current paths through the ohmic region 355. Also, while the N+ islands 353 are coupled to one another to form a single junction diode in the embodiment of FIGS. 10A, 10B, the N+ islands 353 or any subset thereof may alternatively be coupled to distinct conductive nodes in the first conductive layer 365 to form multiple diodes having distinct N+ terminals, but commonly coupled P terminals (i.e., multiple diodes having cathodes coupled in common). As with the diode of FIGS. 9A and 9B, the disposition of the N+ and P+ regions may be reversed and disposed in a lightly doped n-well (or n-type substrate) to form a P⁺/N diode. Also, while active-area islands 353 having square or substantially square aspect ratios are shown (e.g., sides differing in length by 50% or less), the active-area islands or any subset thereof may have different shapes in alternative embodiments including, without limitation, a octagonal shape, hexagonal shape (or any other polygon having multiple sides of substantially uniform length) or if permitted by the fabrication process, circular or substantially circular shapes, thus further increasing the area to perimeter ratio of the P-N junction. More generally, any annular arrangement of the P+ and N+ regions, regardless of the number of sides of the regions, may be used in alternative embodiments.

Although junction diodes have been described in reference to FIGS. 9A/9B and 10A/10B, any structure that provides a similar forward-bias characteristic (i.e., low or negligible current flow until forward-biased by a cut-in voltage that is higher than the power supply voltage but less than an overstress voltage of internal circuitry) may be used within the ESD protection circuits of FIGS. 2, 7 and 8 in alternative embodiments. Such structures, which may include, without limitation, Zener diodes (e.g., heavily doped N+ and P+ regions) butting-junction diodes (N⁺/P and P⁺/N regions disposed directly adjacent each other without intermediary) as well as the junction diodes described above, are collectively referred to herein as diode elements.

It should be noted that the various circuits and layouts disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit and layout expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described circuits and layouts may be processed by a processing entity (e.g., one or more processors) within the computer system in conjunction with execution of one or more other computer programs including, without limitation, net-list generation programs, place and route programs and the like, to generate a representation or image of a physical manifestation of such circuits and layouts. Such representation or image may thereafter be used in device fabrication, for example, by enabling generation of one or more masks that are used to form various components of the circuits and layouts in a device fabrication process.

Section headings have been provided in this detailed description for convenience of reference only, and in no way define, limit, construe or describe the scope or extent of such sections. Also, while the invention has been described with reference to specific embodiments thereof, it will be evident that various modifications and changes may be made thereto without departing from the broader spirit and scope of the invention. Accordingly, the specification and drawings are to be regarded in an illustrative rather than a restrictive sense.

What is claimed is:

1. A diode comprising:
a first doped region;
a first carrier injection region disposed within the first doped region and having a plurality of sides of substantially uniform length; and
an ohmic contact region disposed about a perimeter of the first carrier injection region.

2. The diode of claim 1 wherein the first doped region is lightly doped relative to the first carrier injection region.

3. The diode of claim 1 wherein the first doped region comprises a positively-doped well.

4. The diode of claim 3 wherein the first carrier injection region comprises an increased concentration of negative charge carriers relative to the positively-doped well.

5. The diode of claim 1 further comprising a dielectric material disposed about the perimeter of the first carrier injection region to isolate the plurality of sides of the first carrier injection region from the ohmic contact region.

6. The diode of claim 5 wherein the dielectric is disposed within a trench disposed about the perimeter of the first carrier injection region.

7. The diode of claim 5 wherein the dielectric comprises silicon dioxide.

8. The diode of claim 1 wherein each of the plurality of sides of the first carrier injection region is not more than 50% longer than any other of the plurality of sides of the first carrier injection region.

9. The diode of claim 1 wherein the first carrier injection region is substantially square.

10. The diode of claim 1 wherein the first carrier injection region is substantially octagonal.

11. The diode of claim 1 wherein the first carrier injection region is circular.

12. The diode of claim 1 further comprising a second carrier injection region disposed within the first doped region and having a plurality of sides of substantially uniform length.

13. The diode of claim 1 further comprising a conductive structure coupled to the first carrier injection region and to the second carrier injection region.

14. The diode of claim 13 wherein the conductive structure comprises:
a conductive feature disposed in a conductive layer of an integrated circuit device;
a first conductive via coupled between to the first carrier injection region and the conductive feature; and
a second conductive via coupled between the second carrier injection region and the conductive feature.

15. A diode comprising:
a first doped region;
a plurality of carrier injection regions disposed within the first doped region;
an ohmic contact region disposed about the perimeter of each of the plurality of carrier injection regions; and
a conductive structure coupled to each of the plurality of carrier injection regions.

16. The diode of claim 15 wherein the first doped region comprises a positively-doped well.

17. The diode of claim 16 wherein at least one of the plurality of carrier injection regions comprises an increased concentration of negative charge carriers relative to the positively-doped well.

18. The diode of claim 15 further comprising a dielectric material disposed about the perimeter of at least one of the plurality of carrier injection regions to isolate sides of the at least one of the plurality of carrier injection regions from the ohmic contact region.

19. The diode of claim 18 wherein the dielectric is disposed within a trench disposed about the perimeter of the first carrier injection region.

20. The diode of claim 15 wherein the conductive structure comprises a plurality of conductive vias coupled respectively to the plurality of carrier injection regions.

21. The diode of claim 20 wherein the conductive structure further comprises a conductive feature that contacts each of the plurality of conductive vias to electrically couple each of the plurality of carrier injection regions to one another.

22. The diode of claim 21 wherein the conductive structure is a metal feature dispose in a metal layer of an integrated circuit device.

23. A method of forming a diode, the method comprising:
forming a first doped region in a semiconductor substrate;
forming, within the first doped region, a first carrier injection region having a plurality of sides of substantially uniform length; and
forming an ohmic contact region about a perimeter of the first carrier injection region.

24. The method of claim 23 wherein forming the first doped region comprises forming a positively-doped well.

25. The method of claim 24 wherein forming the first carrier injection region comprises forming a region having an increased concentration of negative charge carriers relative to the positively-doped well.

26. The method of claim 23 further comprising forming a dielectric barrier about the perimeter of the first carrier injection region to isolate the plurality of sides of the first carrier injection region from the ohmic contact region.

27. The method of claim 23 further comprising forming a second carrier injection region within the first doped region.

28. The method of claim 23 wherein forming a first carrier injection region having a plurality of sides of substantially uniform length comprises forming a substantially square carrier injection region.

29. A method of forming a diode, the method comprising:
forming a first doped region within a semiconductor substrate;
forming a plurality of carrier injection regions disposed within the first doped region;
forming an ohmic contact region about the perimeter of each of the plurality of carrier injection regions; and
forming a conductive structure coupled to each of the plurality of carrier injection regions.

30. The method of claim 29 wherein forming the conductive structure comprises forming a plurality of conductive vias that respectively contact the plurality of carrier injection regions.

31. The method of claim 30 wherein forming the conductive structure further comprises forming a conductive feature that contacts each of the plurality of conductive vias to electrically couple each of the plurality of carrier injection regions to one another.

32. Computer-readable media having information embodied therein that includes a description of a diode formed within a substrate of an integrated circuit device, the information including descriptions of:
a first doped region within the substrate of the integrated circuit device;
a first carrier injection region disposed within the first doped region and having a plurality of sides of substantially uniform length; and
an ohmic contact region disposed about a perimeter of the first carrier injection region.
